(19) United States
(12) Patent Application Publication
(10) Pub. No.: US 2026/0255731 A1
(43) Pub. Date: Aug. 27, 2026

(54) MICRO-LEDS WITH PLASMON-ASSISTED RECOMBINATION

(71) Applicant: Hyperlume Inc., Ottawa (CA)

(72) Inventors: Mohsen Asad, Ottawa (CA); Hossein Fariborzi, Auburndale, MA (US); Bilal Janjua, Toronto (CA)

(73) Assignee: Hyperlume Inc., Ottawa (CA)

(21) Appl. No.: 19/064,824

(22) Filed: Feb. 27, 2025

(51) Int. Cl. H10H 20/812; H10H 20/01; H10H 20/816; H10H 20/821; H10H 20/831; H10H 20/857

(52) U.S. Cl. CPC H10H 20/812; H10H 20/017; H10H 20/032; H10H 20/0364; H10H 20/8162; H10H 20/821; H10H 20/8312; H10H 20/857

(57) ABSTRACT

The present disclosure provides a plasmonic light-emitting diode device. The device includes a first conductivity-type semiconductor layer disposed of on a substrate, a multiple quantum well sheet positioned over the first conductivity-type semiconductor layer, and a second conductivity-type semiconductor layer disposed on the multiple quantum well sheet. Additionally, a contact layer is positioned over the second conductivity-type semiconductor layer, wherein the contact layer establishes an ohmic contact. The nanoholes are formed within the first conductivity-type semiconductor layer, wherein a plasmonic metal is at least partially deposited within each nanohole to facilitate surface plasmon resonance.

### TECHNICAL FIELD

The present disclosure generally relates to semiconductor light-emitting devices. Further, the present disclosure particularly relates to a plasmonic light-emitting diode device incorporating nanostructured conductive features to facilitate surface plasmon resonance.

### BACKGROUND

Generally, micro-light emitting diodes (micro-LEDs) have been adopted for high-speed communication applications. Multi-line parallel data transfer enabled by micro-LEDs enables low-power communication between application-specific integrated circuits (ASICs), comprising graphics processing units (GPUs), tensor processing units (TPUs), and memories. Conventionally, micro-LEDs are grown on substrates such as sapphire or silicon, forming polar structures that exhibit limited electro-optical bandwidth. Carrier recombination processes in micro-LEDs must be accelerated to enable higher-speed operation.

Moreover, group III nitride semiconductors, composed of nitrogen and elements such as aluminum (Al), gallium (Ga), and indium (In), have been widely implemented in optoelectronic applications, comprising high-speed communication, lighting, and display technologies. Micro-LEDs utilizing such Group III nitride semiconductors are widely adopted due to compact size, high efficiency, and potential for integration into advanced electronic systems. Reduced thermal resistance associated with micro-LEDs enables operation at high current densities while maintaining low power consumption. A high 3 dB bandwidth and improved light emission properties are supported by such low thermal resistance.

Additionally, micro-LEDs based on gallium nitride (GaN) face fabrication challenges associated with achieving low electrical resistance and high efficiency. Material defects in GaN-based micro-LEDs arise due to high defect densities in epitaxial layers. Strong intrinsic polarization fields further limit performance by inducing charge separation in quantum wells. Lattice mismatches between GaN layers and substrates such as sapphire, silicon, or silicon carbide (SiC) introduce additional strain, leading to defects that degrade material quality. Polarity of GaN in the growth direction causes charge separation effects within quantum wells, reducing carrier recombination efficiency.

Surface plasmons have been employed to enhance the recombination process in quantum wells and quantum dots. Electromagnetic coupling between surface plasmons and excitons enhances radiative recombination rates, facilitating higher-speed optical emission. Nanostructuring or roughening metal surfaces enables stronger coupling between surface plasmons and radiative centers. If the plasmon frequency is matched with the emission frequency of quantum wells, excitons generated in quantum wells couple to surface plasmon modes at metal surfaces. Conventional nanostructure fabrication approaches involve creating such nanostructures on the top surface of LED epitaxial layers. However, such fabrication approaches degrade efficiency due to the presence of a thin p-GaN layer and an electron barrier layer (EBL) within the LED structure.

Other solutions have also been adopted for plasmonic enhancement in LED structures. Nanoparticles of noble metals such as silver (Ag) or gold (Au) have been embedded within undoped GaN layers to facilitate plasmonic coupling. Such nanoparticle-based approaches have demonstrated enhancements in emission properties, but embedding nanoparticles within undoped GaN layers leads to challenges in achieving low electrical resistance. Alternative device geometries involving plasmonic resonators and patterned electrodes have also been employed. However, such alternative device geometries lead to increased fabrication complexity and limitations in electrical performance.

Additional techniques have been utilized to improve coupling efficiency between surface plasmons and quantum wells. Structuring of GaN layers to create sub-wavelength periodic patterns has been employed to optimize plasmonic interactions. Etching nanostructures within GaN layers modifies the interaction between surface plasmons and excitons. Introducing interlayers composed of dielectric materials or metal oxides between GaN and plasmonic metals has been investigated to tune surface plasmon resonance properties. Such interlayer-based approaches influence plasmonic dispersion relations and carrier dynamics within LED structures.

Other existing techniques for enhancing optical emission efficiency in micro-LEDs have involved the deposition of distributed Bragg reflectors (DBRs) and optical cavity engineering. Stacks of alternating high- and low-refractive-index materials have been used to enhance light extraction efficiency through reflection and constructive interference. Microcavity structures have been implemented to confine and direct emitted light to specific angles, enhancing directional emission properties. However, such approaches require precise fabrication control and introduce trade-offs between electrical and optical performance.

In light of the above discussion, there exists an urgent need for solutions that overcome the problems associated with conventional systems and techniques for enhancing radiative recombination and plasmonic coupling efficiency in micro-LED structures.

### SUMMARY

The present disclosure provides a plasmonic light-emitting diode device. A first conductivity-type semiconductor layer is disposed on a substrate. A multiple quantum well sheet is positioned over the first conductivity-type semiconductor layer to facilitate radiative recombination. A second conductivity-type semiconductor layer is disposed on the multiple quantum well sheet. A contact layer is positioned over the second conductivity-type semiconductor layer, wherein the contact layer establishes an ohmic contact to reduce contact resistance. A plurality of nanoholes is formed within the first conductivity-type semiconductor layer, wherein a plasmonic metal is at least partially deposited within each nanohole to facilitate surface plasmon resonance, thereby enhancing light emission.

In an embodiment, the first conductivity-type semiconductor layer comprises an overgrowth layer that enhances material quality and structural integrity. The overgrowth layer improves electrical transport and provides an optimized environment for plasmonic interactions. Each nanohole extends through the overgrowth layer towards the multiple quantum well sheet to facilitate coupling between surface plasmons and excitons. The structural arrangement of the overgrowth layer and nanoholes is optimized to enhance carrier transport and optical properties, improving device efficiency.

In an embodiment, a first electrode is deposited onto the first conductivity-type semiconductor layer, and a second electrode is deposited onto the contact layer. The first electrode and the second electrode facilitate electrical injection and extraction. The optimized electrode placement reduces series resistance and enhances current spreading within the plasmonic light-emitting diode device. The deposition of the electrodes improves electrical characteristics and enables stable device operation under high-current conditions.

In yet another embodiment, the thickness of the first conductivity-type semiconductor layer is in a predefined range, which is selected to balance electrical and optical performance. The thinning of the first conductivity-type semiconductor layer optimizes plasmonic coupling efficiency while maintaining adequate structural stability. The optimized thickness minimizes series resistance while supporting efficient light-matter interactions within the device.

In an embodiment, each nanohole is individually filled with a plasmonic metal, wherein the plasmonic metal is selected from silver, gold, copper, or aluminum. The selection of the plasmonic metal is based on optical properties that enhance light emission through surface plasmon excitation. The deposition process ensures that each nanohole is uniformly filled to achieve consistent plasmonic behavior across the device structure.

According to an embodiment, the first conductivity-type semiconductor layer and the filled plasmonic metal sandwich an interlayer, wherein the interlayer is composed of a material selected from a dielectric material, a metal oxide material, or a semiconductor material. The interlayer modifies the plasmonic resonance frequency to enhance coupling between excitons and surface plasmons. The introduction of the interlayer optimizes plasmonic interactions while maintaining the stability of the semiconductor-metal interface.

In an embodiment, the second conductivity-type semiconductor layer comprises a bandgap electron blocking layer that confines charge carriers within the multiple quantum well sheet. The bandgap electron blocking layer prevents electron overflow, enabling efficient recombination within the quantum wells. The incorporation of the bandgap electron blocking layer enhances carrier confinement and improves the emission efficiency of the plasmonic light-emitting diode device.

In an embodiment, a subwavelength plasmonic metal array is introduced within the first conductivity-type semiconductor layer to facilitate surface plasmon polariton coupling. The subwavelength plasmonic metal array enables strong light-matter interaction by matching plasmonic modes with the quantum well emission wavelength. The plasmonic metal array is optimized to achieve maximum plasmonic enhancement for improved light extraction and emission properties.

In another aspect, the present disclosure provides a method for fabricating a plasmonic light-emitting diode device. A first conductivity-type semiconductor layer is epitaxially grown on a substrate to achieve high crystal quality and maintain lattice matching. A multiple quantum well sheet is positioned over the first conductivity-type semiconductor layer to support radiative recombination. A second conductivity-type semiconductor layer is disposed on the multiple quantum well sheet to facilitate carrier injection and recombination. A contact layer is positioned over the second conductivity-type semiconductor layer to establish an ohmic contact for efficient electrical conduction.

In an embodiment, an ohmic contact is established between the contact layer and the second conductivity-type semiconductor layer to reduce contact resistance and improve carrier injection. The optimized ohmic contact formation minimizes energy losses and enhances the electrical performance of the plasmonic light-emitting diode device. The fabrication of the ohmic contact involves controlled processing steps to achieve uniform conductivity across the device structure.

In an embodiment, a plurality of nanoholes is patterned into the first conductivity-type semiconductor layer to enable plasmonic enhancement. The nanoholes are defined to optimize plasmonic coupling with the multiple quantum well sheet.

In an embodiment, a plasmonic metal is deposited into the nanoholes, wherein the plasmonic metal at least partially fills the nanoholes. The deposition of the plasmonic metal enhances surface plasmon resonance, improving the light emission properties of the device.

In an embodiment, the first conductivity-type semiconductor layer is thinned to a predefined thickness range to optimize electrical and optical performance. The thinning process improves electrical conductivity while enhancing plasmonic coupling efficiency. The optimized thickness minimizes series resistance while preserving the integrity of the semiconductor structure.

In an embodiment, the nanoholes are arranged in a hexagonal pattern, a square pattern, or a quasi-random lattice pattern to control plasmonic mode distribution. The arrangement of the nanoholes influences the interaction between excitons and surface plasmons, optimizing the optical properties of the plasmonic light-emitting diode device. The geometric configuration of the nanoholes is customized to achieve the desired plasmonic resonance conditions.

In an embodiment, the first conductivity-type semiconductor layer comprises an overgrowth layer, wherein the overgrowth layer is deposited using a metal-organic chemical vapor deposition technique or a molecular beam epitaxy technique. The deposition of the overgrowth layer enhances material quality and improves device performance. The overgrowth layer provides structural stability and supports plasmonic interactions within the device.

In an embodiment, via openings are created in the contact layer to provide electrical access to the second conductivity-type semiconductor layer. The formation of the via openings enables reliable electrical connections for current injection. The via openings are defined to enable minimal resistance and efficient carrier transport within the device.

In an embodiment, a first electrode is formed on the first conductivity-type semiconductor layer, and a second electrode is formed on the contact layer. The first electrode and the second electrode facilitate electrical conduction, assuring uniform current distribution across the plasmonic light-emitting diode device. The optimized electrode placement enhances electrical performance and stability under high-current operation.

Further, a removal of the substrate is performed using laser lift-off with a high-energy laser beam to detach the substrate from the first conductivity-type semiconductor layer. The removal of the substrate exposes the first conductivity-type semiconductor layer for subsequent processing, comprising thinning, structuring, and filling of plasmonic metal. The laser lift-off process is optimized to achieve precise substrate detachment without damaging the semiconductor layers.

### BRIEF DESCRIPTION OF THE DRAWINGS

The summary above, as well as the following detailed description of illustrative embodiments, is better understood when read in conjunction with the appended drawings. For the purpose of illustrating the present disclosure, exemplary constructions of the disclosure are shown in the drawings. However, the present disclosure is not limited to specific methods and instrumentalities disclosed herein.

Embodiments of the present disclosure will now be described, by way of example only, with reference to the following diagrams.

FIG. 1 illustrates a plasmonic light-emitting diode (LED) device, in accordance with various implementations of the present disclosure;

FIG. 2 illustrates a method for fabricating a plasmonic light-emitting diode (LED) device, in accordance with embodiments of the present disclosure;

FIG. 3 illustrates a flip-chip bonded light-emitting diode (LED) structure, where epitaxial layers are initially grown on a temporary growth substrate such as sapphire, silicon, or silicon carbide, in accordance with the embodiments of the present disclosure;

FIG. 4 illustrates the process of etching etched nanoholes into a thinned n-GaN layer, in accordance with the embodiments of the present disclosure;

FIG. 5 illustrates the deposition of plasmonic structures into the multiple holes within a thinned n-GaN layer, in accordance with the embodiments of the present disclosure;

FIG. 6 illustrates the process of embedding embedded plasmonic structures within a GaN matrix by overgrowing n-GaN following metal deposition, in accordance with the embodiments of the present disclosure; and

FIG. 7 illustrates the formation of via openings with passivated and electrical isolated sidewalls to provide electrical access to the ohmic p-contact, enabling current injection into the device, in accordance with the embodiments of the present disclosure.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practicing the present disclosure are also possible.

As used herein, the term “plasmonic light-emitting diode device” refers to a semiconductor-based optical emission device that utilizes surface plasmon resonance to influence the recombination of charge carriers and enhance light emission. Such plasmonic light-emitting diode device incorporates a semiconductor structure that comprises multiple layers for charge carrier injection, transport, and recombination. The structure of the plasmonic light-emitting diode device comprises a first conductivity-type semiconductor layer, a second conductivity-type semiconductor layer, and a multiple quantum well sheet that serves as the active emission region. Surface plasmon resonance is facilitated by nanostructures or plasmonic materials embedded within the semiconductor structure. Such plasmonic light-emitting diode devices may be used in applications requiring high-speed optical communication, display technologies, or energy-efficient lighting systems.

As used herein, the term “first conductivity-type semiconductor layer” refers to a semiconductor layer that possesses an electrical conductivity primarily determined by a specific type of charge carrier. Such first conductivity-type semiconductor layer may be formed from Group III-V materials, Group IV materials, or compound semiconductor materials doped to exhibit majority carrier transport. The doping of such first conductivity-type semiconductor layer may be achieved through intentional introduction of donor or acceptor impurities to regulate electrical properties. Such first conductivity-type semiconductor layer serves as a carrier injection region and a structural support for additional semiconductor layers. Similar semiconductor layers are found in laser diodes, photodetectors, and heterostructure field-effect transistors.

As used herein, the term “substrate” refers to a structural base upon which semiconductor layers and device components are deposited or grown. Such substrate provides mechanical support and determines the initial crystallographic orientation of overlying semiconductor layers. Such substrate may be composed of insulating, semiconducting, or conducting materials depending on the requirements of the semiconductor process. The substrate can be made up of silicon, sapphire, silicon carbide, gallium arsenide, and indium phosphide. Such substrate may be removed in certain device fabrication methods to improve optical or electrical performance. Techniques such as laser lift-off, mechanical detachment, and chemical etching may be employed to remove or modify such substrate in semiconductor processing.

As used herein, the term “multiple quantum well sheet” refers to a layered semiconductor structure consisting of alternating thin layers of different bandgap materials. Such multiple quantum well sheet serves as the active emission region where carrier recombination occurs, leading to photon generation. The thickness and composition of such multiple quantum well sheet influences charge carrier confinement and optical emission properties. The multiple quantum well sheet may be composed of gallium nitride/indium gallium nitride heterostructures, aluminum gallium arsenide/gallium arsenide heterostructures, and silicon/germanium quantum well structures. Such multiple quantum well sheet may be used in light-emitting diodes, laser diodes, and photonic devices requiring wavelength-specific emission properties.

As used herein, the term “second conductivity-type semiconductor layer” refers to a semiconductor layer possessing electrical conductivity determined by charge carriers of opposite polarity to those present in the first conductivity-type semiconductor layer. Such second conductivity-type semiconductor layer functions as a counter-doped region to facilitate charge carrier recombination within the multiple quantum well sheet. Such second conductivity-type semiconductor layer may be fabricated using doping techniques such as ion implantation, diffusion, or in situ doping during epitaxial growth. The materials used for such second conductivity-type semiconductor layer comprise gallium nitride, indium phosphide, gallium arsenide, and silicon carbide. Such second conductivity-type semiconductor layer is commonly found in heterojunction devices, bipolar junction transistors, and p-n junction diodes.

As used herein, the term “contact layer” refers to a conductive or semiconducting layer positioned at the interface of a semiconductor structure to facilitate electrical contact with external circuitry. Such contact layer forms an ohmic contact with the underlying semiconductor material, minimizing electrical resistance and making sure efficient charge carrier injection or extraction. The materials used for such contact layer comprise indium tin oxide, nickel-gold alloys, titanium-platinum-gold stacks, and transparent conductive oxides. Such contact layer may be deposited using sputtering, evaporation, or chemical vapor deposition techniques. Similar structures are used in laser diodes, photodetectors, and thin-film transistors.

As used herein, the term “ohmic contact” refers to an electrical junction that allows charge carriers to flow with minimal resistance and without significant rectification effects. Such ohmic contact is formed through the selection of appropriate metal-semiconductor interfaces or through techniques such as annealing and interfacial doping. The materials used to form such ohmic contact comprise palladium, nickel, gold, silver, and transparent conductive oxides. Such ohmic contact is utilized in semiconductor devices where low-resistance electrical connections are required, such as in light-emitting diodes, field-effect transistors, and photodetectors.

As used herein, the term “nanohole” refers to a submicron-scale cavity or void formed within a semiconductor layer to enable optical, electrical, or plasmonic interactions. Such nanohole may be patterned using techniques such as electron beam lithography, nanoimprint lithography, or chemical etching. The geometric dimensions and periodicity of such nanohole influence light extraction efficiency, plasmonic resonance, or charge carrier transport. The applications involving such nanohole structures may be selected from photonic crystal waveguides, quantum dot arrays, and nanoporous semiconductor membranes.

As used herein, the term “plasmonic metal” refers to a metallic material that exhibits surface plasmon resonance effects when interacting with electromagnetic radiation. Such plasmonic metal supports collective oscillations of free electrons at metal-dielectric interfaces, enabling enhanced optical interactions. Examples of plasmonic metal materials comprise silver, gold, copper, and aluminum. The plasmonic metal is used in optical sensors, plasmonic waveguides, and nanophotonic devices to manipulate light at subwavelength scales.

As used herein, the term “surface plasmon resonance” refers to a physical phenomenon wherein collective oscillations of free electrons at a metal-dielectric interface couple with incident electromagnetic waves. Such surface plasmon resonance is influenced by the material properties of the plasmonic metal, the surrounding dielectric environment, and the wavelength of incident light. Surface plasmon resonance is utilized in applications such as biosensing, nanophotonics, and light-emitting diode structures to modify light-matter interactions.

As used herein, the term “first electrode” refers to an electrically conductive structure that facilitates charge injection or extraction within a semiconductor device. Such first electrode is positioned on the first conductivity-type semiconductor layer to enable electrical connection with external circuitry. The materials used for such first electrode comprise indium tin oxide, aluminum, gold, and silver. Such first electrode is found in photonic devices, optoelectronic circuits, and high-speed semiconductor components.

As used herein, the term “second electrode” refers to an electrically conductive structure positioned on the contact layer to enable charge carrier transport within the semiconductor device. By using second electrode, proper electrical interfacing can be performed between the semiconductor layers and external drive electronics. Such second electrode can be made up of materials selected from nickel-gold bilayers, platinum, titanium, and conducting polymers. Such second electrode is commonly implemented in optoelectronic devices, comprising micro-light-emitting diodes and laser diodes.

As used herein, the term “epitaxially growing” refers to a semiconductor fabrication process wherein crystalline layers are deposited onto a substrate in a manner that maintains crystallographic alignment. Such epitaxially growing process comprises techniques such as molecular beam epitaxy, metal-organic chemical vapor deposition, and hydride vapor phase epitaxy. Epitaxially grown layers are used in high-performance semiconductor devices such as quantum cascade lasers, heterojunction bipolar transistors, and optical modulators.

As used herein, the term “depositing” refers to the process of adding material onto a surface using techniques such as physical vapor deposition, chemical vapor deposition, or electroplating. Such depositing process is used to form metallic, dielectric, or semiconducting layers within microelectronic and photonic devices.

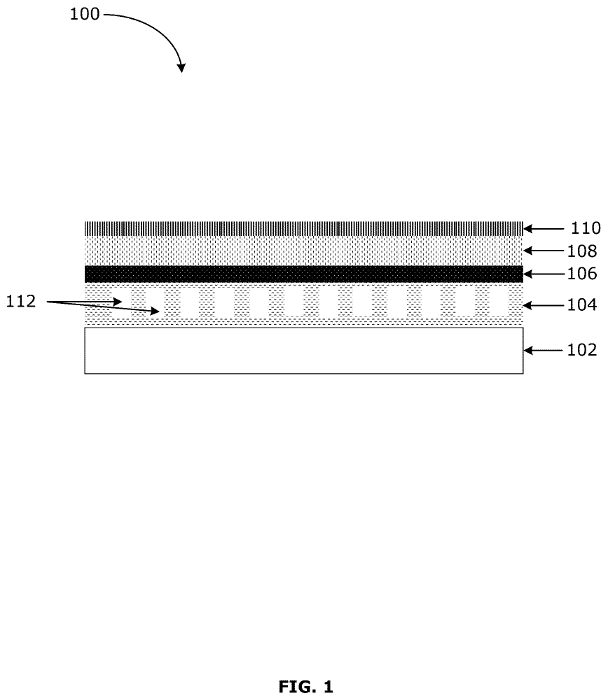

FIG. 1 illustrates a plasmonic light-emitting diode (LED) device (100), in accordance with various implementations of the present disclosure. The plasmonic LED device (100) comprises a first conductivity-type semiconductor layer (104) is disposed on a substrate (102) and serves as a foundational layer for subsequent semiconductor structures. Said first conductivity-type semiconductor layer (104) is doped to exhibit n-type conductivity and supports electron transport for charge injection. Said first conductivity-type semiconductor layer (104) is formed from a compound semiconductor material such as gallium nitride or a similar material with suitable electronic and optical properties. The doping of said first conductivity-type semiconductor layer (104) is achieved through intentional incorporation of donor impurities to regulate carrier concentration and conductivity characteristics. The crystalline structure of said first conductivity-type semiconductor layer (104) is maintained to enable compatibility with overlying layers. Said first conductivity-type semiconductor layer (104) is deposited using epitaxial growth techniques to achieve high crystallinity and lattice continuity with underlying substrate (102) material. The thickness of said first conductivity-type semiconductor layer (104) is selected to balance optical and electrical properties, enabling efficient carrier transport and controlled light emission characteristics. Said first conductivity-type semiconductor layer (104) provides structural integrity to support the deposition of a multiple quantum well sheet (MQW) (106) and a second conductivity-type semiconductor layer (108). The interface between said first conductivity-type semiconductor layer (104) and said substrate (102) influences defect formation and strain characteristics, affecting the overall performance of the plasmonic light-emitting diode (LED) device (100). The selection of said substrate (102) material is based on factors such as lattice matching, thermal expansion properties, and compatibility with semiconductor processing techniques. Said substrate (102) may be composed of materials such as silicon, sapphire, or silicon carbide, depending on the specific application requirements. Said first conductivity-type semiconductor layer (104) may undergo additional processing steps such as thinning or structuring to optimize optical coupling and carrier injection properties. The integration of nanostructures or plasmonic elements within said first conductivity-type semiconductor layer (104) influences emission characteristics and surface plasmon interactions.

In an embodiment, the multiple quantum well sheet (MQW) (106) is positioned over said first conductivity-type semiconductor layer (104) and serves as an active region for radiative recombination. Said MQW sheet (106) consists of alternating layers of semiconductor materials with varying bandgap energies to facilitate charge carrier confinement and photon emission. The composition and thickness of said MQW sheet (106) are optimized to control wavelength emission properties and carrier recombination efficiency. Said MQW sheet (106) is grown using epitaxial techniques to maintain high crystallinity and interface integrity with adjacent semiconductor layers. The alternating well and barrier layers within said MQW sheet (106) are fabricated to achieve quantum confinement effects, influencing electron-hole recombination dynamics. The selection of materials for said MQW sheet (106) comprises compound semiconductors such as indium gallium nitride or gallium arsenide, depending on emission wavelength requirements. The interface between said MQW sheet (106) and said first conductivity-type semiconductor layer (104) influences carrier transport and recombination rates, impacting optical output characteristics. The thickness and composition of individual layers within said MQW sheet (106) are controlled to achieve desired emission spectra and efficiency levels. The doping concentration and material composition of said MQW sheet (106) optimize charge carrier dynamics and optical response. Growth conditions for said MQW sheet (106) are controlled to achieve minimal defect formation and uniform material properties. The interaction of emitted photons from said MQW sheet (106) with plasmonic structures within said plasmonic light-emitting diode (LED) device (100) influences emission characteristics and coupling efficiency. Said MQW sheet (106) may incorporate strain compensation layers to mitigate structural deformations caused by lattice mismatches with adjacent semiconductor layers.

In an embodiment, the second conductivity-type semiconductor layer (108) is disposed on said MQW sheet (106) and facilitates hole injection for charge carrier recombination. Said second conductivity-type semiconductor layer (108) is doped to exhibit p-type conductivity and provides a charge transport pathway for holes. Said second conductivity-type semiconductor layer (108) is formed from a semiconductor material such as gallium nitride, aluminum gallium nitride, or similar compound materials with appropriate electrical and optical characteristics. The doping of said second conductivity-type semiconductor layer (108) is achieved through controlled incorporation of acceptor impurities to regulate hole concentration and conductivity. The crystalline integrity of said second conductivity-type semiconductor layer (108) is maintained to assure compatibility with said MQW sheet (106) and said contact layer (110). Said second conductivity-type semiconductor layer (108) is deposited using epitaxial growth techniques to achieve uniform thickness and optimized charge transport properties. The interface between said second conductivity-type semiconductor layer (108) and said MQW sheet (106) influences hole injection efficiency and carrier confinement. The selection of material composition and doping profile for said second conductivity-type semiconductor layer (108) minimizes resistance and optimize recombination dynamics. The surface properties of said second conductivity-type semiconductor layer (108) impact light extraction and device efficiency. Said second conductivity-type semiconductor layer (108) may incorporate additional layers such as an electron blocking layer to enhance carrier recombination within said MQW sheet (106). Growth parameters for said second conductivity-type semiconductor layer (108) are controlled to minimize defect formation and enable uniform material characteristics.

In an embodiment, a contact layer (110) is positioned over said second conductivity-type semiconductor layer (108) and establishes an ohmic contact to facilitate efficient charge carrier injection. Said contact layer (110) is composed of p-type gallium nitride (p-GaN) and provides a conductive interface for electrical connections. The material composition and doping concentration of said contact layer (110) are optimized to reduce contact resistance and improve current injection efficiency. Said contact layer (110) is deposited using epitaxial growth techniques to enable high-quality interface formation with said second conductivity-type semiconductor layer (108). The thickness of said contact layer (110) is controlled to balance electrical conductivity and optical transparency. The surface properties of said contact layer (110) influence light extraction and interface stability with metal electrodes. Said contact layer (110) maintains structural integrity while minimizing resistive losses. Processing techniques such as annealing and surface treatment may be applied to said contact layer (110) to optimize its electrical characteristics. The interface between said contact layer (110) and external electrodes achieves stable ohmic contact formation.

In an embodiment, a plurality of nanoholes (112) is formed within said first conductivity-type semiconductor layer (104), wherein a plasmonic metal is at least partially deposited within each nanohole (112) to facilitate surface plasmon resonance. Said nanoholes (112) are structured to achieve localized electromagnetic interactions and enhanced optical coupling. The geometric dimensions and spatial distribution of said nanoholes (112) are optimized to control plasmonic effects within said plasmonic light-emitting diode (LED) device (100). The selection of plasmonic metal deposited within said nanoholes (112) comprises materials such as silver, gold, copper, or aluminum. The interaction between said plasmonic metal and said MQW sheet (106) influences carrier recombination rates and emission properties. The patterning of said nanoholes (112) is achieved through techniques such as lithography or etching to achieve precise structural configurations. The controlled deposition of plasmonic metal within said nanoholes (112) modulates optical emission characteristics and enhances surface plasmon resonance. The arrangement and periodicity of said nanoholes (112) achieves targeted plasmonic interactions. Said nanoholes (112) may be embedded within additional layers or modified to achieve desired optical properties.

In an embodiment, the first conductivity-type semiconductor layer (104) comprises an overgrowth layer. The overgrowth layer is formed through epitaxial deposition to provide a high-quality crystalline structure and improve material integrity. The deposition of the overgrowth layer reduces defect density, mitigating strain effects caused by lattice mismatch between the first conductivity-type semiconductor layer (104) and the adjacent MQW sheet (106). The overgrowth layer provides additional thickness, allowing for controlled doping distribution and improved carrier transport. The composition of the overgrowth layer comprises materials such as gallium nitride or aluminum gallium nitride, depending on electronic and optical characteristics. The growth conditions of the overgrowth layer are controlled to achieve uniform thickness and smooth surface morphology. The overgrowth layer is structured to accommodate the formation of a plurality of nanoholes (112) for plasmonic integration. The interface between the overgrowth layer and the first conductivity-type semiconductor layer (104) minimizes interface states that could affect carrier recombination. The overgrowth layer serves as a platform for integrating additional nanostructures that influence plasmonic resonance and photon extraction. The incorporation of the overgrowth layer into the first conductivity-type semiconductor layer (104) enables improved device stability and enhanced emission characteristics. The overgrowth layer is processed using etching and planarization techniques to achieve precise thickness control and surface uniformity.

In an embodiment, each nanohole (112) extends through the overgrowth layer towards the MQW sheet (106). The formation of each nanohole (112) is achieved using lithographic techniques followed by dry or wet etching to obtain a well-defined geometry. The nanohole (112) geometry and depth are controlled to enable proper alignment with the MQW sheet (106) while maintaining the structural stability of the overgrowth layer. The patterning process for the nanohole (112) optimizes optical and plasmonic coupling effects. The spacing and periodicity of the nanohole (112) are selected to enhance light-matter interactions and facilitate charge carrier recombination. The interface between the nanohole (112) and the overgrowth layer is processed to achieve smooth sidewalls and minimize scattering losses. The depth of the nanohole (112) is precisely controlled to reach the proximity of the MQW sheet (106) without inducing damage or affecting quantum confinement properties. The presence of the nanohole (112) in the overgrowth layer influences photon extraction efficiency by modifying the optical path and altering refractive index properties. The arrangement of the nanohole (112) achieves enhanced surface plasmon resonance effects. The overgrowth layer surrounding the nanohole (112) acts as a mechanical support while maintaining electrical continuity within the first conductivity-type semiconductor layer (104).

In an embodiment, a first electrode is deposited onto the first conductivity-type semiconductor layer (104), and a second electrode is deposited onto the contact layer (110). The first electrode provides electrical contact to the first conductivity-type semiconductor layer (104) to enable efficient carrier injection. The second electrode is deposited onto the contact layer (110) to establish a conductive interface with the second conductivity-type semiconductor layer (108). The material selection for the first electrode and the second electrode comprises metals such as titanium, gold, silver, or aluminum, depending on electrical and optical compatibility. The deposition of the first electrode and the second electrode is achieved through sputtering, evaporation, or electroplating techniques to make sure uniform adhesion and optimal conductivity. The thickness of the first electrode and the second electrode is controlled to minimize series resistance and maintain device stability. The interface between the first electrode and the first conductivity-type semiconductor layer (104) is processed to achieve low contact resistance and high charge carrier injection efficiency. The interface between the second electrode and the contact layer (110) is optimized to facilitate hole injection into the second conductivity-type semiconductor layer (108). The spatial arrangement of the first electrode and the second electrode distributes current uniformly across the device structure. The first electrode and the second electrode may comprise additional layers such as adhesion layers or diffusion barriers to improve electrical performance and long-term stability.

In an embodiment, the thickness of the first conductivity-type semiconductor layer (104) is in a range of 50 nm to 500 nm (selected from distinct ranges such as 50 nm to 100 nm, 100 nm to 200 nm, 200 nm to 300 nm, 300 nm to 400 nm and 400 nm to 500 nm). The thickness of the first conductivity-type semiconductor layer (104) is selected to optimize electrical transport properties while maintaining compatibility with the MQW sheet (106) and the second conductivity-type semiconductor layer (108). The controlled thickness of the first conductivity-type semiconductor layer (104) influences carrier injection efficiency and resistance characteristics. The deposition of the first conductivity-type semiconductor layer (104) is performed using epitaxial growth techniques to achieve the desired thickness while preserving crystal quality. The thickness range of the first conductivity-type semiconductor layer (104) is determined based on material properties, lattice strain considerations, and intended optical interactions. The interface between the first conductivity-type semiconductor layer (104) and the substrate (102) is processed to affirm structural integrity and defect minimization. The thickness of the first conductivity-type semiconductor layer (104) affects the formation of the nanohole (112), influencing plasmonic coupling properties. The selection of the thickness range for the first conductivity-type semiconductor layer (104) balances light extraction efficiency, optical confinement, and electrical conductivity. The thinning or structuring of the first conductivity-type semiconductor layer (104) may be performed post-deposition to refine electrical and plasmonic characteristics.

In an embodiment, each nanohole (112) is, individually, filled with a plasmonic metal, wherein the plasmonic metal is selected from silver (Ag), gold (Au), copper (Cu), or aluminum (Al). The deposition of the plasmonic metal within each nanohole (112) is performed using methods such as evaporation, sputtering, or electrochemical deposition. The plasmonic metal forms a conductive interface that facilitates localized surface plasmon resonance interactions. The selection of the plasmonic metal is based on optical properties, comprising plasmonic resonance wavelength and reflectivity characteristics. The thickness and distribution of the plasmonic metal within each nanohole (112) are controlled to assure uniform plasmonic response and minimize scattering losses. The adhesion of the plasmonic metal to the first conductivity-type semiconductor layer (104) is optimized to prevent material degradation and diffusion effects. The interaction of the plasmonic metal with emitted photons from the MQW sheet (106) influences radiative recombination dynamics. The spatial arrangement and periodicity of the nanohole (112) influence the coupling efficiency between the plasmonic metal and the semiconductor structure. The presence of the plasmonic metal within each nanohole (112) enables enhanced optical extraction and emission modulation. The composition and deposition parameters of the plasmonic metal aid to achieve desired plasmonic resonance conditions. The interface between the plasmonic metal and the surrounding semiconductor structure enhances charge carrier interactions and minimizes resistive losses.

In an embodiment, the first conductivity-type semiconductor layer (104) and the filled plasmonic metal sandwich an interlayer, wherein the interlayer is composed of a material selected from a dielectric material, a metal oxide material, or a semiconductor material to modify plasmonic resonance frequency. The interlayer is deposited between the first conductivity-type semiconductor layer (104) and the plasmonic metal to influence charge carrier dynamics and optical interactions. The interlayer is formed using deposition techniques such as atomic layer deposition, chemical vapor deposition, or sputtering to achieve thickness control. The material selection for the interlayer is based on refractive index properties, electrical conductivity, and compatibility with adjacent layers. The dielectric material within the interlayer may comprise silicon dioxide or silicon nitride, providing insulation and charge confinement effects. The metal oxide material within the interlayer may comprise aluminum oxide or hafnium oxide, influencing plasmonic coupling properties. The semiconductor material within the interlayer may comprise gallium nitride or indium gallium nitride, facilitating controlled carrier transport while modifying plasmonic resonance frequency. The interlayer thickness is controlled to achieve targeted plasmonic interactions without introducing excessive optical losses. The interlayer composition and spatial distribution influence localized electromagnetic field interactions and charge carrier confinement. The interface between the interlayer and the plasmonic metal is processed to enable stable adhesion and prevent material diffusion. The interlayer modifies the resonance conditions of the plasmonic metal by altering the local dielectric environment.

In an embodiment, the second conductivity-type semiconductor layer (108) comprises a bandgap electron blocking layer configured to confine charge carriers within the MQW sheet (106). The bandgap electron blocking layer is deposited as part of the second conductivity-type semiconductor layer (108) to restrict electron overflow beyond the MQW sheet (106). The bandgap electron blocking layer is composed of a semiconductor material with a higher bandgap than the surrounding layers, forming an energy barrier that prevents excess electron leakage. The material selection for the bandgap electron blocking layer comprises aluminum gallium nitride or indium aluminum nitride, depending on carrier confinement and band alignment requirements. The deposition of the bandgap electron blocking layer is performed using epitaxial growth techniques to achieve high interface quality and minimal defect formation. The thickness of the bandgap electron blocking layer is controlled to balance charge confinement with efficient hole injection. The interface between the bandgap electron blocking layer and the MQW sheet (106) influences carrier transport and radiative recombination properties. The doping concentration of the bandgap electron blocking layer is optimized to minimize resistance while maintaining effective charge blocking characteristics. The spatial distribution of the bandgap electron blocking layer optimizes emission wavelength stability and efficiency. The bandgap electron blocking layer modifies charge carrier recombination dynamics within the MQW sheet (106) by confining electrons while allowing hole transport. The presence of the bandgap electron blocking layer influences optical emission characteristics by controlling carrier recombination zones.

In an embodiment, a subwavelength plasmonic metal array is introduced within the first conductivity-type semiconductor layer (104) to facilitate surface plasmon polariton (SPP) coupling. The subwavelength plasmonic metal array is structured to support collective charge oscillations at the metal-semiconductor interface, enabling enhanced light-matter interactions. The subwavelength plasmonic metal array is formed using nanolithographic patterning followed by metal deposition to achieve spatial arrangement. The material selection for the subwavelength plasmonic metal array comprises silver, gold, copper, or aluminum, based on optical properties and plasmonic resonance conditions. The spacing and periodicity of the subwavelength plasmonic metal array are controlled to achieve resonant coupling with incident photons and charge carriers. The interaction between the subwavelength plasmonic metal array and the MQW sheet (106) influences charge carrier recombination and photon emission characteristics. The structural dimensions of the subwavelength plasmonic metal array are optimized to achieve localized electromagnetic field enhancement. The deposition of the subwavelength plasmonic metal array is performed using techniques such as electron beam lithography, nanoimprint lithography, or self-assembled nanoparticle patterning. The interface between the subwavelength plasmonic metal array and the first conductivity-type semiconductor layer (104) is processed to achieve stable adhesion and minimal resistive losses. The subwavelength plasmonic metal array modifies surface plasmon dispersion properties by controlling the interaction between incident electromagnetic waves and the plasmonic metal.

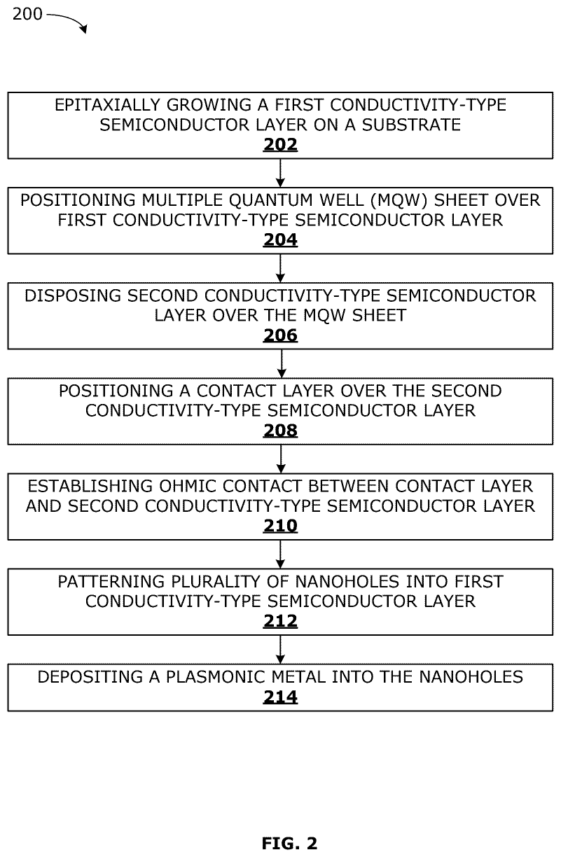

FIG. 2 illustrates a method for fabricating a plasmonic light-emitting diode (LED) device (100), in accordance with embodiments of the present disclosure. At step 202, the first conductivity-type semiconductor layer (104) is epitaxially grown on a substrate (102). The deposition of the first conductivity-type semiconductor layer (104) is performed using a crystal growth process that maintains lattice alignment with the substrate (102). The material composition of the first conductivity-type semiconductor layer (104) comprises gallium nitride or an equivalent compound semiconductor with appropriate electrical and optical properties. The doping of the first conductivity-type semiconductor layer (104) is achieved through the controlled introduction of donor impurities to establish n-type conductivity. The thickness of the first conductivity-type semiconductor layer (104) is selected based on electrical transport properties and optical confinement requirements. The growth conditions, comprising temperature and precursor gas composition, are controlled to achieve high crystal quality. The interface between the first conductivity-type semiconductor layer (104) and the substrate (102) is processed to minimize lattice mismatch effects and defect formation.

At step 204, a MQW sheet (106) is positioned over the first conductivity-type semiconductor layer (104). The MQW sheet (106) is formed through epitaxial growth, creating alternating layers of semiconductor materials with varying bandgap energies to facilitate charge carrier confinement. The thickness and composition of individual quantum well layers are controlled to achieve emission wavelength targeting and efficient radiative recombination. The material selection for the MQW sheet (106) comprises indium gallium nitride or equivalent semiconductors suitable for bandgap engineering. The MQW sheet (106) is deposited in a manner that preserves crystalline integrity, thereby low defect density. The interface between the MQW sheet (106) and the first conductivity-type semiconductor layer (104) optimizes charge carrier transport and recombination dynamics.

At step 206, a second conductivity-type semiconductor layer (108) is disposed over the MQW sheet (106). The second conductivity-type semiconductor layer (108) is doped to exhibit p-type conductivity by incorporating acceptor impurities. The material composition of the second conductivity-type semiconductor layer (108) comprises gallium nitride or an equivalent semiconductor with appropriate electrical characteristics. The second conductivity-type semiconductor layer (108) facilitates hole injection into the MQW sheet (106) to support charge carrier recombination. The deposition of the second conductivity-type semiconductor layer (108) is controlled to maintain uniform doping concentration and minimize interface defects. The interface between the second conductivity-type semiconductor layer (108) and the MQW sheet (106) influences carrier confinement and recombination efficiency. The thickness of the second conductivity-type semiconductor layer (108) is optimized to balance electrical conductivity and optical transparency.

At step 208, a contact layer (110) is positioned over the second conductivity-type semiconductor layer (108). The contact layer (110) is composed of p-type gallium nitride and serves as an interface for establishing electrical connections. The deposition of the contact layer (110) is performed using epitaxial techniques to maintain compatibility with the second conductivity-type semiconductor layer (108). The thickness of the contact layer (110) is controlled to optimize electrical conduction while preserving optical emission properties. The interface between the contact layer (110) and the second conductivity-type semiconductor layer (108) is processed to reduce interface resistance and improve carrier injection efficiency. The contact layer (110) is structured to support the formation of an ohmic contact with external electrodes.

At step 210, an ohmic contact is established between the contact layer (110) and the second conductivity-type semiconductor layer (108). The formation of the ohmic contact involves the deposition of a conductive material that minimizes contact resistance and enables efficient hole injection. The selection of contact materials comprises metals such as nickel-gold or platinum-based alloys to achieve stable electrical performance. The interface between the ohmic contact and the contact layer (110) is processed using annealing techniques to enhance conductivity. The thickness and composition of the ohmic contact are controlled to affirm reliable electrical operation. The spatial arrangement of the ohmic contact facilitates uniform current distribution within the device structure.

At step 212, a plurality of nanoholes (112) is patterned into the first conductivity-type semiconductor layer (104). The patterning process is performed using lithographic techniques followed by etching to define nanohole (112) structures with dimensions. The depth and diameter of each nanohole (112) are controlled to achieve targeted plasmonic coupling effects. The spatial arrangement of the nanohole (112) is optimized to facilitate enhanced optical interactions within the device structure. The patterning process provides uniformity and reproducibility across the entire surface of the first conductivity-type semiconductor layer (104). The etching process used for nanohole (112) formation is selected based on material compatibility and desired structural characteristics.

At step 214, a plasmonic metal is deposited into the nanoholes (112), wherein the plasmonic metal at least partially fills the nanoholes (112). The deposition of the plasmonic metal is performed using methods such as evaporation, sputtering, or electrochemical deposition to assure controlled material distribution. The material selection for the plasmonic metal comprises silver, gold, copper, or aluminum, based on optical and electrical properties. The interface between the plasmonic metal and the first conductivity-type semiconductor layer (104) is processed to achieve stable adhesion and minimal interfacial resistance. The thickness and coverage of the plasmonic metal within each nanohole (112) are optimized to support surface plasmon resonance effects. The spatial arrangement of the plasmonic metal influences localized electromagnetic interactions and emission characteristics. The plasmonic metal deposition process is controlled to maintain uniformity across multiple nanoholes (112) while preventing unintended material diffusion into adjacent semiconductor regions. The interaction between the plasmonic metal and the MQW sheet (106) is influenced by the nanohole (112) depth, material composition, and geometric configuration.

In an embodiment, the thinning of the first conductivity-type semiconductor layer (104) is performed via a chemical etching technique, a reactive ion etching (RIE) technique, an inductively coupled plasma (ICP) etching technique, or a mechanical polishing technique. The thinning process is conducted to achieve a controlled reduction in thickness while maintaining uniformity across the first conductivity-type semiconductor layer (104). The chemical etching technique utilizes selective etchants to remove semiconductor material while preserving surface integrity. The reactive ion etching technique removes material through ion bombardment under controlled plasma conditions. The inductively coupled plasma etching technique employs high-density plasma to achieve material removal with controlled selectivity. The mechanical polishing technique uses abrasive techniques to achieve planarization and uniform thickness reduction. The choice of thinning technique is based on material compatibility, surface quality requirements, and integration with subsequent processing steps. The interface between the first conductivity-type semiconductor layer (104) and adjacent layers is maintained to make sure minimal damage during the thinning process. The thinning parameters, comprising etchant concentration, plasma energy, or polishing force, are controlled to achieve the target thickness without introducing excessive surface roughness or structural defects.

In an embodiment, the nanoholes (112) are patterned into the first conductivity-type semiconductor layer (104) using an electron beam lithography (EBL) technique, a nanoimprint lithography (NIL) technique, or an interference laser lithography technique. The electron beam lithography technique employs a focused electron beam to define nanohole (112) patterns with high resolution, enabling spatial control of nanostructure placement. The nanoimprint lithography technique utilizes a patterned template to transfer nanohole (112) structures onto the first conductivity-type semiconductor layer (104) through a mechanical imprinting process. The interference laser lithography technique employs optical interference patterns to create periodic nanohole (112) arrays across the semiconductor surface. The patterning of the nanoholes (112) is controlled to achieve uniform size, depth, and spatial distribution across the first conductivity-type semiconductor layer (104). The material properties of the first conductivity-type semiconductor layer (104) are considered to optimize lithographic resolution and etching selectivity. The nanohole (112) formation process is followed by a selective etching step to remove semiconductor material and expose well-defined nanostructures. The depth of each nanohole (112) is adjusted to reach the required proximity to the MQW sheet (106) without compromising material integrity.

In an embodiment, the via openings are created in the contact layer (110) to provide electrical access to the second conductivity-type semiconductor layer (108). The via openings are defined using photolithographic masking and etching techniques to achieve controlled dimensions and placement. The etching process for the via openings is performed using dry or wet etching methods, enabling selective removal of material without excessive undercutting. The dimensions of the via openings are optimized to balance electrical contact reliability and mechanical stability. The contact layer (110) is processed to maintain interface quality and prevent material degradation during the via formation process. The arrangement of the via openings facilitates uniform current distribution across the second conductivity-type semiconductor layer (108). The via openings provide a conductive path for charge carrier injection, supporting efficient device operation. The formation of the via openings is followed by surface treatment processes to enhance metal adhesion and minimize interface resistance.

In an embodiment, the first electrode is formed on the first conductivity-type semiconductor layer (104) and a second electrode is formed on the contact layer (110). The first electrode provides electrical contact to the first conductivity-type semiconductor layer (104), enabling efficient charge carrier injection. The second electrode establishes an electrical interface with the contact layer (110) to facilitate hole transport into the second conductivity-type semiconductor layer (108). The deposition of the first electrode and the second electrode is performed using techniques such as evaporation, sputtering, or electroplating. The material selection for the first electrode and the second electrode comprises metals such as titanium, gold, silver, or aluminum, depending on electrical and optical compatibility. The thickness of the first electrode and the second electrode is optimized to balance conductivity and mechanical stability. The interface between the first electrode and the first conductivity-type semiconductor layer (104) is processed to achieve low contact resistance and stable adhesion. The interface between the second electrode and the contact layer (110) minimizes interface defects and supports efficient carrier injection.

In an embodiment, the first conductivity-type semiconductor layer (104) comprises an overgrowth layer, wherein the overgrowth layer is deposited using a metal-organic chemical vapor deposition (MOCVD) technique or a molecular beam epitaxy (MBE) technique. The overgrowth layer provides structural and electronic benefits by reducing defect density and improving material quality. The MOCVD technique involves gas-phase precursors reacting at the substrate surface to enable controlled layer-by-layer deposition. The MBE technique utilizes thermal evaporation of elemental sources under ultra-high vacuum conditions to achieve thickness control and crystallinity. The composition of the overgrowth layer comprises materials such as gallium nitride or aluminum gallium nitride, depending on application requirements. The overgrowth layer is deposited to improve charge carrier transport and mitigate strain effects caused by lattice mismatches. The growth parameters for the overgrowth layer, including temperature, precursor flow rates, and pressure conditions, are optimized to affirm high crystalline quality.

In an embodiment, a removal of the substrate (102) is performed using a laser lift-off (LLO) with a high-energy laser beam to detach the substrate (102) from the first conductivity-type semiconductor layer (104) to expose the first conductivity-type semiconductor layer (104) for subsequent processing, including thinning, structuring, and filling of plasmonic metal. The laser lift-off technique applies a pulsed laser to the interface between the substrate (102) and the first conductivity-type semiconductor layer (104), inducing localized energy absorption and material decomposition. The laser parameters, comprising wavelength, pulse duration, and energy density, are controlled to achieve precise detachment without damaging the first conductivity-type semiconductor layer (104). The removal of the substrate (102) is performed under vacuum or controlled atmospheric conditions to prevent contamination or oxidation.

In an embodiment, the first conductivity-type semiconductor layer (104) is thinned to a thickness in the range of 50 nm to 500 nm. The thinning process is conducted using etching or mechanical removal techniques to achieve controlled thickness reduction. The thinning parameters are adjusted to maintain uniformity while preserving the electrical and optical properties of the first conductivity-type semiconductor layer (104). The final thickness is selected based on charge carrier transport characteristics, plasmonic coupling requirements, and integration with subsequent fabrication steps.

In an embodiment, the nanoholes (112) are arranged in a hexagonal pattern, a square pattern, or a quasi-random lattice pattern to control plasmonic mode distribution. The arrangement of the nanoholes (112) is selected based on optical interaction requirements and structural considerations. The hexagonal pattern provides uniform spacing for periodic plasmonic coupling, while the square pattern supports defined alignment with external optical elements. The quasi-random lattice pattern enables broadband plasmonic interactions by disrupting periodic constraints. The selection of the nanohole (112) arrangement is determined based on wavelength-specific optical responses and light extraction properties. The geometric configuration of the nanoholes (112) influences localized electromagnetic interactions and charge carrier recombination rates.

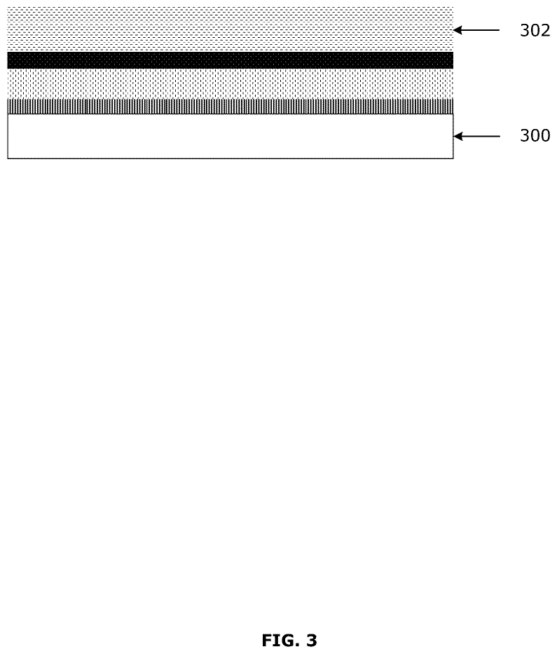

FIG. 3 illustrates a flip-chip bonded light-emitting diode (LED) structure, where epitaxial layers are initially grown on a temporary growth substrate such as sapphire, silicon, or silicon carbide, in accordance with the embodiments of the present disclosure. The epitaxial layers comprise a thinned n-GaN layer (302) (similar to the first conductivity-type semiconductor layer (104) of FIG. 1), a multiple quantum well (MQW) region (similar to the MQW sheet (106) of FIG. 1), and a p-GaN layer (similar to the second conductivity-type semiconductor layer (108) of FIG. 1), forming an active region responsible for light emission. Following the completion of epitaxial growth, the p-side contacts are bonded to a carrier substrate (300) using an epoxy adhesive or a metal bonding process. The bonding process facilitates stable thermal management and mechanical stability for subsequent fabrication steps. After bonding, the temporary growth substrate is removed to expose the thinned n-GaN layer (302) to the topmost surface. The removal process is performed using laser lift-off, where a high-energy laser beam is applied at the interface between the temporary growth substrate and the n-GaN layer (302), causing separation without affecting the underlying epitaxial structure. Following the removal of the temporary growth substrate, the exposed n-GaN layer (302) undergoes a thinning process using chemical etching, mechanical polishing, or inductively coupled plasma etching. The controlled thinning of the n-GaN layer (302) reduces series resistance and improves electrical transport while maintaining structural integrity. The reduction in thickness enhances plasmonic coupling efficiency when integrating metallic nanostructures within the LED structure. The optimized configuration provides improved electrical performance, high-speed operation, and enhanced optical efficiency, making the structure suitable for high-performance micro-LEDs and plasmonic LED applications.

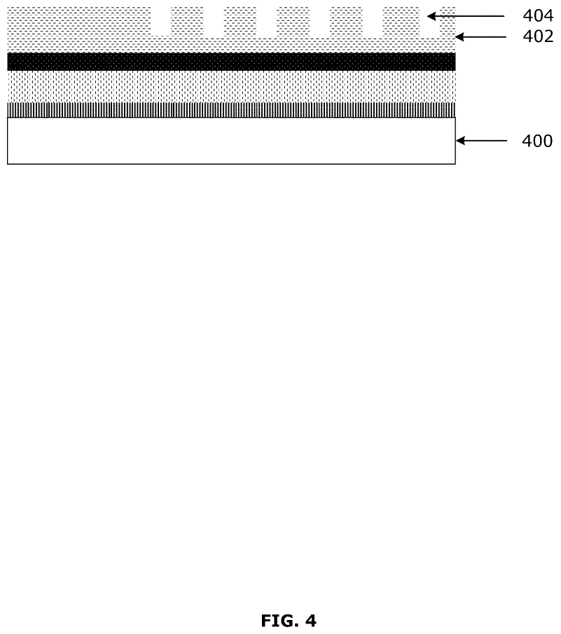

FIG. 4 illustrates the process of etching etched nanoholes (404) into a thinned n-GaN layer (402), in accordance with the embodiments of the present disclosure. The etched nanoholes (404) (similar to the nanoholes (112) of FIG. 1) are introduced to modify surface plasmon excitation characteristics and facilitate coupling with the underlying multiple quantum well (similar to the MQW sheet (106) of FIG. 1). The size, shape, and spatial arrangement of the etched nanoholes (404) influence localized electromagnetic interactions and charge carrier dynamics. The fabrication of the etched nanoholes (404) involves lithographic patterning followed by etching to achieve controlled depth and sidewall profiles. The lithographic patterning process employs high-resolution techniques such as electron beam lithography for sub-100 nm feature sizes or nanoimprint lithography for large-area patterning using predefined templates. Interference laser lithography is used for periodic pattern formation based on laser interference effects. Following pattern definition, the etched nanoholes (404) are formed using reactive ion etching, inductively coupled plasma etching, or ion milling, affirming precision and control over sidewall geometry. The depth and aspect ratio of the etched nanoholes (404) are adjusted to enhance light-matter interactions and surface plasmon resonance properties. The interaction between the etched nanoholes (404) and the plasmonic metal deposited within influences localized field distribution and emission characteristics. The structural integrity of the thinned n-GaN layer (402) (similar to the first conductivity-type semiconductor layer (104) of FIG. 1 and the thinned n-GaN layer (302) of FIG. 3) is maintained during the etching process to prevent mechanical or electrical degradation. The introduction of the etched nanoholes (404) enhances optical extraction efficiency while influencing charge carrier recombination properties. The etched nanoholes (404) are arranged in a pattern optimized for targeted plasmonic effects, supporting applications in micro-LEDs and plasmonic LEDs. The carrier substrate (400) (similar to the carrier substrate (300) of FIG. 3) provides structural support during processing and subsequent operation.

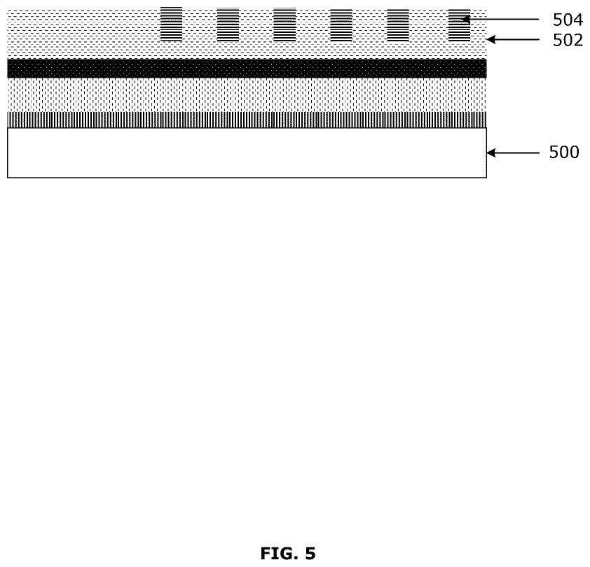

FIG. 5 illustrates the deposition of plasmonic structures (504) into the multiple holes (similar to the etched nanoholes (404) of FIG. 4 and the nanoholes (112) of FIG. 1) within a thinned n-GaN layer (502) (similar to the thinned n-GaN layer (402) of FIG. 4, the thinned n-GaN layer (302) of FIG. 3 and the first conductivity-type semiconductor layer (104) of FIG. 1), in accordance with the embodiments of the present disclosure. The plasmonic structures (504) are introduced by depositing plasmonic metals such as silver, aluminum, copper, or gold, which modify the interaction between the electromagnetic field and the surrounding semiconductor material. The deposition of the plasmonic structures (504) within the multiple holes can be performed using techniques such as evaporation, sputtering, or electrochemical deposition.

In an embodiment, the plasmonic structures (504) within the multiple holes influence localized surface plasmon resonance characteristics by altering the near-field electromagnetic environment. The depth and volume fraction of the plasmonic structures (504) are optimized to tune the plasmonic coupling efficiency with the multiple quantum well section (similar to the MQW sheet (106) of FIG. 1) beneath the thinned n-GaN layer (502). The carrier substrate (500) provides mechanical support during processing and subsequent operation, maintaining stability for the integration of the plasmonic structures (504). The interface between the plasmonic structures (504) and the thinned n-GaN layer (502) affects the propagation of surface plasmon polaritons and influences charge carrier dynamics within the semiconductor material.

In an embodiment, the periodic arrangement of the plasmonic structures (504) within the multiple holes is controlled to support coupling between surface plasmon polaritons and photonic emission modes. The introduction of the interlayer between the plasmonic structures (504) and the thinned n-GaN layer (502) enables additional tuning of plasmonic resonance characteristics. The interlayer may comprise dielectric materials, metal oxides, or semiconductor layers, which alter the dispersion relation of surface plasmons and influence the efficiency of light-matter interactions. The presence of the plasmonic structures (504) modifies the charge carrier recombination process, influencing radiative efficiency and emission dynamics.

In an embodiment, the structural arrangement of the plasmonic structures (504) within the multiple holes enables control over the localized density of optical states, supporting applications requiring enhanced emission properties. The periodicity, shape, and size of the plasmonic structures (504) are adjusted to achieve controlled resonance conditions, where the spatial alignment of the plasmonic structures (504) enables efficient optical coupling within the thinned n-GaN layer (502). The deposition process for the plasmonic structures (504) is followed by excess metal removal techniques such as angle etching, mechanical polishing, or chemical etching to assure that the plasmonic structures (504) remain confined within the etched nanoholes (504).

In an embodiment, the controlled placement of the plasmonic structures (504) influences the interaction between the multiple quantum well section and surface plasmons, supporting applications in high-speed light-emitting devices. The integration of the plasmonic structures (504) within the thinned n-GaN layer (502) provides structural and optical benefits, influencing the radiative emission characteristics of the device. The spatial distribution and patterning of the plasmonic structures (504) determine the coupling efficiency between surface plasmon modes and the radiative recombination process. The selection of plasmonic metal for the plasmonic structures (504) influences the resonance wavelength and interaction strength with the quantum well emission, where the material composition is adjusted based on optical performance requirements. The periodic lattice arrangement of the plasmonic structures (504) facilitates surface plasmon polariton excitation, where the periodicity is controlled based on targeted optical coupling effects. The carrier substrate (500) (similar to the carrier substrate (400) of FIG. 4 and carrier substrate (300) of FIG. 3) provides a foundation for the fabrication and subsequent operation of the plasmonic-enhanced device structure.

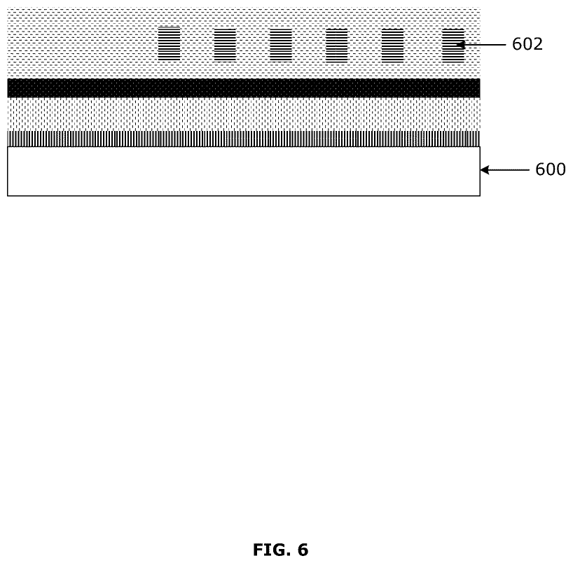

FIG. 6 illustrates the process of embedding embedded plasmonic structures (602) (similar to the plasmonic structures (504) of FIG. 5) within a GaN matrix by overgrowing n-GaN following metal deposition, in accordance with the embodiments of the present disclosure. The overgrowth process provides structural and functional benefits by encapsulating the embedded plasmonic structures (602) within the semiconductor material. The overgrowth of n-GaN prevents oxidation and thermal degradation of the embedded plasmonic structures (602), enabling long-term stability and maintaining plasmonic properties. The deposition parameters, including growth temperature, precursor flow rate, and doping concentration, are controlled to achieve a uniform n-GaN layer while preserving the optical characteristics of the embedded plasmonic structures (602). The presence of the embedded plasmonic structures (602) influences charge carrier transport by reducing series resistance and improving electrical conductivity within the n-GaN layer. The interface between the embedded plasmonic structures (602) and the surrounding n-GaN layer facilitates controlled plasmonic resonance, enabling interaction with the multiple quantum well region. The carrier substrate (600) (similar to the carrier substrate (500) of FIG. 5, the carrier substrate (400) of FIG. 4 and carrier substrate (300) of FIG. 3) provides structural support throughout the fabrication process.

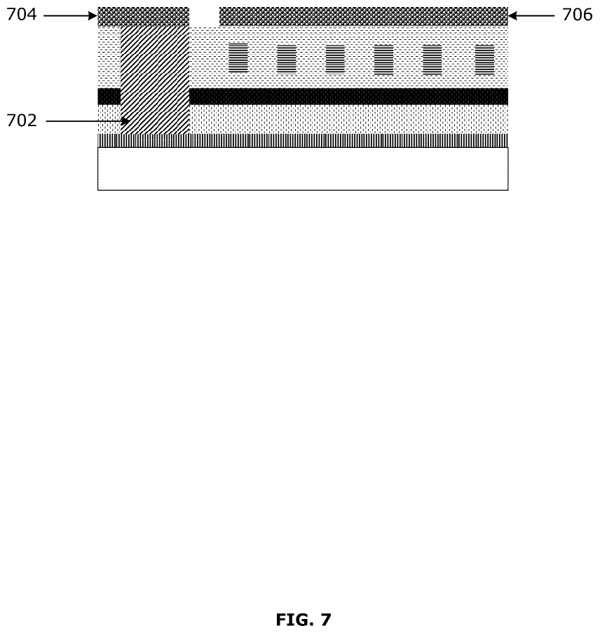

FIG. 7 illustrates the formation of via openings (702) to provide electrical access to the ohmic p-contact, enabling current injection into the device, in accordance with the embodiments of the present disclosure. The via openings (702) extend through the overgrown semiconductor layers to establish a conductive path between the anode (704) and the lower semiconductor region. The formation of the via openings (702) is performed using dry etching techniques to achieve controlled dimensions and precise alignment with the underlying layers. The sidewall is passivated and electrically isolated to prevent shortening of the diode. The anode (704) is deposited onto the exposed p-contact region, facilitating hole injection into the active quantum well region. The cathode (706) is formed on the opposite surface, assuring a conductive interface with the n-doped semiconductor layer. The spatial arrangement of the via openings (702) is optimized to support uniform current distribution, minimizing series resistance. The carrier substrate (700) (similar to carrier substrate (300) of FIG. 3, carrier substrate (400) of FIG. 4, carrier substrate (500) of FIG. 5 and carrier substrate (600) of FIG. 6) provides mechanical stability and thermal management during processing and subsequent operation, maintaining the structural integrity of the semiconductor stack.

In an embodiment, a first conductivity-type semiconductor layer (104) disposed on a substrate (102) provides a structural foundation and facilitates charge carrier transport. The selection of substrate (102) material influences thermal conductivity, lattice matching, and overall device performance. The first conductivity-type semiconductor layer (104) is doped to exhibit n-type conductivity, enabling efficient electron injection and transport. The interface between the first conductivity-type semiconductor layer (104) and the substrate (102) affects defect density, carrier mobility, and optical properties. The thickness of the first conductivity-type semiconductor layer (104) is controlled to balance optical confinement and electrical resistance.

In an embodiment, a MQW sheet (106) positioned over the first conductivity-type semiconductor layer (104) forms an active emission region. The MQW sheet (106) consists of alternating layers of materials with varying bandgap energies to achieve carrier confinement and efficient radiative recombination. The selection of well and barrier materials determines emission wavelength and recombination dynamics. The thickness and composition of the MQW sheet (106) are provided to optimize charge carrier localization and minimize non-radiative losses. The MQW sheet (106) influences optical output characteristics through quantum confinement effects.

In an embodiment, a second conductivity-type semiconductor layer (108) disposed on the MQW sheet (106) facilitates hole injection and recombination with electrons. The second conductivity-type semiconductor layer (108) is doped to exhibit p-type conductivity, enhancing carrier transport and injection efficiency. The material composition of the second conductivity-type semiconductor layer (108) is selected based on optical transparency and electrical conductivity requirements. The interface between the second conductivity-type semiconductor layer (108) and the MQW sheet (106) impacts carrier recombination rates and light emission properties. The thickness of the second conductivity-type semiconductor layer (108) is controlled to balance carrier injection efficiency with optical transmission.

In an embodiment, a contact layer (110) positioned over the second conductivity-type semiconductor layer (108) establishes an ohmic contact, facilitating charge injection and reducing interface resistance. The material composition of the contact layer (110) comprises p-type gallium nitride, optimizing carrier transport characteristics. The interface between the contact layer (110) and the second conductivity-type semiconductor layer (108) is processed to achieve minimal contact resistance and stable electrical performance. The thickness of the contact layer (110) is optimized to balance optical transmission and electrical conduction. The contact layer (110) influences device stability and long-term reliability under operating conditions.

In an embodiment, a plurality of nanoholes (112) formed within the first conductivity-type semiconductor layer (104) enables plasmonic interactions, modifying emission characteristics. The nanoholes (112) are structured to facilitate light-matter interactions and surface plasmon resonance. The spatial arrangement and depth of the nanoholes (112) influence optical extraction efficiency and localized field enhancement. The formation of nanoholes (112) modifies charge carrier distribution and emission properties. The nanohole (112) dimensions are controlled to optimize optical coupling and minimize scattering losses.

In an embodiment, a plasmonic metal at least partially deposited within each nanohole (112) facilitates surface plasmon resonance, enhancing emission efficiency. The plasmonic metal is selected from silver, gold, copper, or aluminum based on optical and electrical properties. The deposition of the plasmonic metal influences localized electromagnetic field interactions and modifies recombination dynamics. The thickness and distribution of the plasmonic metal are controlled to provide uniform plasmonic response. The interface between the plasmonic metal and the surrounding semiconductor material affects optical coupling and charge carrier behavior.

In an embodiment, the first conductivity-type semiconductor layer (104) comprises an overgrowth layer, reducing defect density and improving structural integrity. The overgrowth layer is deposited to enhance material quality and minimize dislocation density. The composition of the overgrowth layer is selected to match lattice properties and carrier transport characteristics. The thickness and uniformity of the overgrowth layer influence optical and electrical performance. The overgrowth layer facilitates subsequent nanohole (112) formation and plasmonic integration.

In an embodiment, each nanohole (112) extends through the overgrowth layer towards the MQW sheet (106), modifying charge carrier and photon interactions. The extension of nanoholes (112) through the overgrowth layer optimizes plasmonic coupling and light extraction efficiency. The depth and placement of each nanohole (112) are controlled to achieve targeted emission wavelength manipulation. The interaction between the extended nanoholes (112) and the MQW sheet (106) influences recombination dynamics and optical properties.

In an embodiment, the first electrode deposited onto the first conductivity-type semiconductor layer (104) and a second electrode deposited onto the contact layer (110) facilitate electrical conduction. The first electrode establishes electrical contact with the first conductivity-type semiconductor layer (104) to support electron injection. The second electrode interfaces with the contact layer (110) to enable hole transport. The material selection for the first electrode and the second electrode is based on conductivity and stability requirements.

In an embodiment, the first conductivity-type semiconductor layer (104) is thinned to a thickness in the range of 50 nm to 500 nm to optimize optical and electrical properties. The thinning process is conducted using etching or polishing techniques to achieve controlled thickness reduction. The final thickness of the first conductivity-type semiconductor layer (104) influences plasmonic coupling efficiency and charge carrier transport characteristics. The interface properties of the thinned first conductivity-type semiconductor layer (104) affect light extraction and electrical resistance. The relation between the thickness of first conductivity-type semiconductor layer (104) and the multiple optical and electrical parameters are depicted in Table. 1.

TABLE 1

| Thickness | Plasmonic | Charge | | |
|---|---|---|---|---|
| Range | Coupling | Carrier | Light | Electrical |
| (nm) | Efficiency | Transport | Extraction | Resistance |
| 50-100 | +++++ | ++ | +++++ | ++++ |
| 100-200 | ++++ | +++ | ++++ | +++ |
| 200-300 | +++ | ++++ | +++ | ++ |
| 300-400 | ++ | +++++ | ++ | + |
| 400-500 | + | +++++ | + | + |

In an embodiment, the effect of thinning the first conductivity-type semiconductor layer (104) from 50 nm to 500 nm is analyzed across plasmonic coupling efficiency, charge carrier transport, light extraction, and electrical resistance. A thinner layer enhances plasmonic coupling and light extraction but increases resistance, while a thicker layer improves charge transport but reduces plasmonic effects.

In an embodiment, the first conductivity-type semiconductor layer (104) and the filled plasmonic metal sandwich an interlayer, modifying plasmonic resonance frequency. The interlayer is composed of a dielectric material, a metal oxide material, or a semiconductor material, influencing localized optical interactions. The thickness and composition of the interlayer are optimized to achieve desired plasmonic coupling characteristics. The interface between the interlayer and the plasmonic metal affects surface plasmon propagation and resonance properties.

In an embodiment, the second conductivity-type semiconductor layer (108) comprises a bandgap electron blocking layer, confining charge carriers within the MQW sheet (106). The bandgap electron blocking layer prevents electron overflow and enhances recombination within the MQW sheet (106). The material selection for the bandgap electron blocking layer is based on band alignment and carrier confinement characteristics. The thickness and doping concentration of the bandgap electron blocking layer influence charge carrier transport and optical emission stability.

In an embodiment, a subwavelength plasmonic metal array is introduced within the first conductivity-type semiconductor layer (104) to facilitate surface plasmon polariton (SPP) coupling. The spatial arrangement of the subwavelength plasmonic metal array influences electromagnetic field confinement and optical interaction properties. The material selection for the subwavelength plasmonic metal array is based on plasmonic resonance characteristics. The periodicity and orientation of the subwavelength plasmonic metal array affect photon coupling efficiency and emission wavelength tuning.

What is claimed is:

1. A plasmonic light-emitting diode (LED) device (100), comprising:
a first conductivity-type semiconductor layer (104) disposed on a substrate (102);
a multiple quantum well (MQW) sheet (106) positioned over the first conductivity-type semiconductor layer (104);
a second conductivity-type semiconductor layer (108) disposed on the MQW sheet (106);
a contact layer (110) positioned over the second conductivity-type semiconductor layer (108), wherein the contact layer (110) establishes an ohmic contact; and
a plurality of nanoholes (112) formed within the first conductivity-type semiconductor layer (104), wherein a plasmonic metal is at least partially deposited within each nanohole (112) to facilitate surface plasmon resonance.

2. The plasmonic LED device (100) of claim 1, wherein the first conductivity-type semiconductor layer (104) comprises an overgrowth layer.

3. The plasmonic LED device (100) of claim 2, wherein each nanohole (112) extends through the overgrowth layer towards the MQW sheet (106).

4. The plasmonic LED device (100) of claim 1, further comprising:
a first electrode deposited onto the first conductivity-type semiconductor layer (104); and
a second electrode deposited onto the contact layer (110).

5. The plasmonic LED device (100) of claim 1, wherein a thickness of the first conductivity-type semiconductor layer (104) is in a range of 50 nm to 500 nm.

6. The plasmonic LED device (100) of claim 1, wherein each of the nanohole (112) is, individually, filled with a plasmonic metal, wherein the plasmonic metal is selected from silver (Ag), gold (Au), copper (Cu), or aluminum (Al).

7. The plasmonic LED device (100) of claim 6, wherein the first conductivity-type semiconductor layer (104) and the filled plasmonic metal sandwiches an interlayer, wherein the interlayer is composed of a material selected from a dielectric material, a metal oxide material, or a semiconductor material to modify plasmonic resonance frequency.

8. The plasmonic LED device (100) of claim 1, wherein the second conductivity-type semiconductor layer (108) comprises a bandgap electron blocking layer configured to confine the charge carriers within the MQW sheet (106).

9. The plasmonic LED device (100) of claim 1, wherein a subwavelength plasmonic metal array is introduced within the first conductivity-type semiconductor layer (104) to facilitate surface plasmon polariton (SPP) coupling.

10. A method for fabricating a plasmonic light-emitting diode (LED) device (100), comprising:
epitaxially growing a first conductivity-type semiconductor layer (104) on a substrate (102);
positioning a multiple quantum well (MQW) sheet (106) over the first conductivity-type semiconductor layer (104);
disposing of a second conductivity-type semiconductor layer (108) over the MQW sheet (106);
positioning a contact layer (110) over the second conductivity-type semiconductor layer (108);
establishing an ohmic contact between the contact layer (110) and the second conductivity-type semiconductor layer (108);
patterning a plurality of nanoholes (112) into the first conductivity-type semiconductor layer (104); and
depositing a plasmonic metal into the nanoholes (112), wherein the plasmonic metal at least partially fills the nanoholes (112).

11. The method of claim 10, wherein thinning of the first conductivity-type semiconductor layer (104) is performed via a chemical etching technique, a reactive ion etching (RIE) technique, an inductively coupled plasma (ICP) etching technique, or a mechanical polishing technique.

12. The method of claim 10, wherein the nanoholes (112) are patterned into the first conductivity-type semiconductor layer (104) using an electron beam lithography (EBL) technique, a nanoimprint lithography (NIL) technique, or an interference laser lithography technique.

13. The method of claim 10, wherein via the openings are created in the contact layer (110) to provide electrical access to the second conductivity-type semiconductor layer (108).

14. The method of claim 10, wherein a first electrode is formed on the first conductivity-type semiconductor layer (104) and a second electrode is formed on the contact layer (110).

15. The method of claim 10, wherein the first conductivity-type semiconductor layer (104) comprises an overgrowth layer, wherein the overgrowth layer is deposited using a metal-organic chemical vapor deposition (MOCVD) technique or a molecular beam epitaxy (MBE) technique.

16. The method of claim 10, wherein a removal of the substrate (102) is performed using a laser lift-off (LLO) with a high-energy laser beam to detach the substrate (102) from the first conductivity-type semiconductor layer (104) to expose the first conductivity-type semiconductor layer (104) for subsequent processing, including thinning, structuring, and filling of plasmonic metal.

17. The method of claim 10, wherein the first conductivity-type semiconductor layer (104) is thinned to a thickness in the range of 50 nm to 500 nm.

18. The method of claim 10, wherein the nanoholes (112) are arranged in a hexagonal pattern, a square pattern, or a quasi-random lattice pattern to control plasmonic mode distribution.
